(19) United States
(12) Patent Application Publication
(10) Pub. No.: US 2005/0153539 A1
(43) Pub. Date: Jul. 14, 2005

(54) Method of forming interconnection lines in a semiconductor device

(75) Inventors: Hye-Soo Shin, Seoul (KR); Do-Yul Yoo, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(73) Assignee: Samsung Electronics Co., Ltd.

(21) Appl. No.: 11/012,687

(22) Filed: Dec. 16, 2004

(30) Foreign Application Priority Data
Jan. 12, 2004 (KR) 2004-1967

(51) Int. Cl. H01L 21/20; H01L 21/4763

(52) U.S. Cl. 438/636; 438/631; 438/624; 438/638

(57) ABSTRACT

A method of forming interconnection lines in a semiconductor device is disclosed. According to the method, a trench is formed in a semiconductor substrate and a scattered reflection layer is formed on the overall surface of the semiconductor substrate including the trench. The scattered reflection layer increases an optical energy reflection rate of a light source used in a photolithography process, thereby providing sufficient energy to completely expose photoresist used to form a photoresist pattern in the trench.

### BACKGROUND OF THE INVENTION

1. Field of the Invention

The present invention relates generally to a method of fabricating a semiconductor device, and more particularly, to a method of forming interconnection lines in a semiconductor device.

A claim of priority is made to Korean Patent Application No. 10-2004-0001967 filed Jan. 12, 2004, the disclosure of which is hereby incorporated by reference in its entirety.

2. Description of the Related Art

The development of semiconductor devices has increased dramatically in order to keep pace with the rapid proliferation of information processing and storage media such as computers. Modern semiconductor devices typically demand a high storage capacity and a high operating speed. In order to satisfy these demands, improved fabrication techniques have been developed for semiconductor devices to increase their level of integration, reliability, and operating speed. One important factor for improving fabrication techniques for semiconductor devices is developing better technologies for forming electrical interconnections.

In conventional semiconductor devices, aluminum has been used to form electrical interconnections due to its low contact resistance and ease of fabrication. However, in highly integrated semiconductor devices, aluminum interconnection structures are prone to problems like junction spike failures, electro-migration, etc. As a result, a material having a lower resistance than aluminum is desired in order to increase the response speed of the semiconductor device.

Recently, many semiconductor devices have adopted copper interconnections having low resistance and good electro-migration characteristics. Also, electrical interconnections employing low-k dielectric insulating layers have been widely used. Unfortunately, copper is not readily etched using the etchants or etch gases typically employed in fabrication processes. Further, etch conditions for etching copper are difficult to maintain. Moreover, where an effective etchant or etch gas is employed, it rapidly diffuses through silicon or metal layers. Therefore, a conventional photolithography process cannot be employed to form copper interconnections, and instead a damascene process is typically used. In particular, a dual damascene process capable of concurrently forming conductive lines and contacts is used.

A dual damascene structure comprises a via hole or a contact hole where a contact for connecting lower conductive elements is formed, and a groove or a trench where a conductive interconnection line is formed. The dual damascene structure is typically formed using one of three etching techniques. In a first method, a contact hole (or via hole) is formed and then a trench (or groove) is formed. In a second method, a trench is formed and then a contact hole is formed. In a third method, a contact hole and a trench are formed concurrently.

These methods can be characterized according to whether the contact hole or the trench is formed first. Accordingly, the appropriate method can be selected depending on the relative sizes of the trench and the contact hole and the degree of allowable misalignment between the trench and the contact hole.

Among the above-described methods, the second method is most commonly used because the process is simple and misalignment between the trench and the contact hole is easily managed within allowable limits.

A conventional method of forming interconnection lines in a semiconductor device will now be described with reference to several accompanying drawings.

FIG. 1 is a planar view illustrating a layout of interconnection lines formed in a semiconductor device by a conventional method. FIGS. 2a through 2e are cross-sectional views illustrating a conventional method of forming interconnection lines in a semiconductor device. Figures on the left side of FIGS. 2a through 2e, are cross-sectional views taken along a line between I and I′ in FIG. 1. Figures on the right side of FIGS. 2a through 2e, are cross-sectional views taken along a line between II and II′ in FIG. 1.

Referring to FIG. 1, an interconnection line 20 is formed in a straight line along an insulating interlayer 12 (See, FIG. 2a) used to electrically insulate various device elements in a semiconductor substrate 10 (See, FIG. 2a). A contact 30 is formed to selectively connect various device elements under insulating interlayer 12 or semiconductor substrate 10 to interconnection line 20. Interconnection line 20 and contact 30 have a dual damascene structure.

Referring to FIG. 2a, insulating interlayer 12 is formed on semiconductor substrate 10 and a hard mask layer 14 and a preventive reflection layer 16 are sequentially stacked on insulating interlayer 12. Photoresist is deposited on preventive reflection layer 16 using a photolithography process, thereby forming a first photoresist pattern 18. First photoresist pattern 18 has an opening of width M and is typically formed using a photolithography process.

Referring to FIG. 2b, preventive reflection layer 16, hard mask layer 14, and a portion of insulating interlayer 12 are removed using first photoresist pattern 18 as an etch mask, thereby forming a trench T or a groove. Once trench T is formed, first photoresist pattern 18 is removed.

Referring to FIG. 2c, photoresist is deposited on semiconductor substrate 10 and trench T. Using the photolithography process, at least two second photoresist patterns 19 intersecting trench T are formed, thereby defining a contact hole C (See, FIG. 2d). Contact hole C is used to penetrate insulating interlayer 12 and thereby expose semiconductor substrate 10 in a subsequent etching process. Second photoresist pattern 19 is formed thicker inside trench T than on preventive reflection layer 16.

Referring to FIG. 2d, a portion of insulating interlayer 12 inside trench T is removed using second photoresist pattern 19 as an etch mask, thereby forming contact hole C exposing a portion of semiconductor substrate 10. Once contact hole C is formed, second photoresist pattern 20 is removed.

Referring to FIG. 2e, a metal layer 22 is formed on the overall surface of semiconductor substrate 10 including contact hole C. Metal layer 22 is chemically and mechanically polished or etch-backed. Semiconductor substrate 10 is planarized to expose preventive reflection layer 16, thereby forming the interconnection lines.

The conventional method of forming interconnection lines in a semiconductor device has a number of shortcomings, a few of which will now be described.

In the conventional method of forming interconnection lines in a semiconductor device, insufficient energy is transferred from a light source to photoresist deposited inside trench T during a photolithography process used to form second photoresist pattern 19. The photoresist is absorbed into preventive reflection layer 16 or hard mask layer 14, thus generating photoresist scum inside trench T when the photoresist is developed. Due to the photoresist scum, the critical dimension of the contact hole is reduced and the contact hole is not well formed, thereby deteriorating the reliability of the device.

Therefore, a method of forming interconnect lines in a semiconductor device without generating photoresist scum in the trench is desired.

### SUMMARY OF THE INVENTION

The present invention provides a method of forming interconnection lines in a semiconductor device such that photoresist scum is prevented from forming inside a trench during the formation of a photoresist pattern crossing the trench. The present invention also allows the precise formation of a contact hole so as to improve the reliability of a device.

According to one embodiment of the present invention, a method of forming interconnection lines in a semiconductor device comprises; forming an insulating interlayer on a semiconductor substrate, forming a preventive reflection layer on the insulating interlayer, and forming a first photoresist pattern on the preventive reflection layer. The method further comprises removing the preventive reflection layer and a portion of the insulating interlayer to a predetermined depth, thereby forming a trench. The method further comprises removing the first photoresist pattern, forming a scattered reflection layer on the semiconductor substrate having the trench formed thereon, and forming a second photoresist pattern intersecting the trench. The method still further comprises forming a contact hole inside the trench using the second photoresist pattern as an etch mask, thereby exposing the semiconductor substrate, forming a metal layer on the semiconductor substrate including the contact hole, and planarizing the semiconductor substrate by chemically and mechanically polishing the metal layer to expose the preventive reflection layer or the insulating interlayer.

The second photoresist pattern typically has the shape of at least two bars or dots.

Thus, in one embodiment of the present invention, the method of forming the connection interconnection lines in a semiconductor device allows the photoresist inside the trench to be supplied with sufficient energy from a light source during the photolithography process used to form the photoresist pattern intersecting the trench such that photoresist scum is prevented from being generated in a portion of the semiconductor substrate where the contact hole is formed. Sufficient energy is supplied to the photoresist due to a silicon oxide layer having a predetermined thickness formed on the overall surface of the semiconductor substrate having the trench formed thereon. Because no photoresist scum is generated, the reliability of the semiconductor device is therefore increased.

### BRIEF DESCRIPTION OF THE DRAWINGS

The accompanying drawings illustrate several selected embodiments of the present invention, and are incorporated in and constitute a part of this specification. Like reference numerals refer to like elements throughout the drawings and the written description.

In the Drawings:

FIG. 1 is a planar view illustrating a layout of interconnection lines formed in a semiconductor device by a conventional method;

FIGS. 2a through 2d are cross-sectional views illustrating a conventional method of forming interconnection lines in a semiconductor device;

FIG. 3 is a planar view illustrating a layout of interconnection lines formed in a semiconductor device according to one embodiment of the present invention;

FIGS. 4a through 4f are cross-sectional views illustrating a method of forming interconnection lines in a semiconductor device according to one embodiment of the present invention;

FIG. 5 is a stereoscopic photograph illustrating a result of forming second photoresist patterns in a dual damascene structure using a single layer;

FIG. 6 is a photograph illustrating a result of forming second photoresist patterns in a dual damascene structure using conventional technology;

FIG. 7 is a photograph illustrating a result of forming second photoresist patterns in a dual damascene structure according to the present invention.

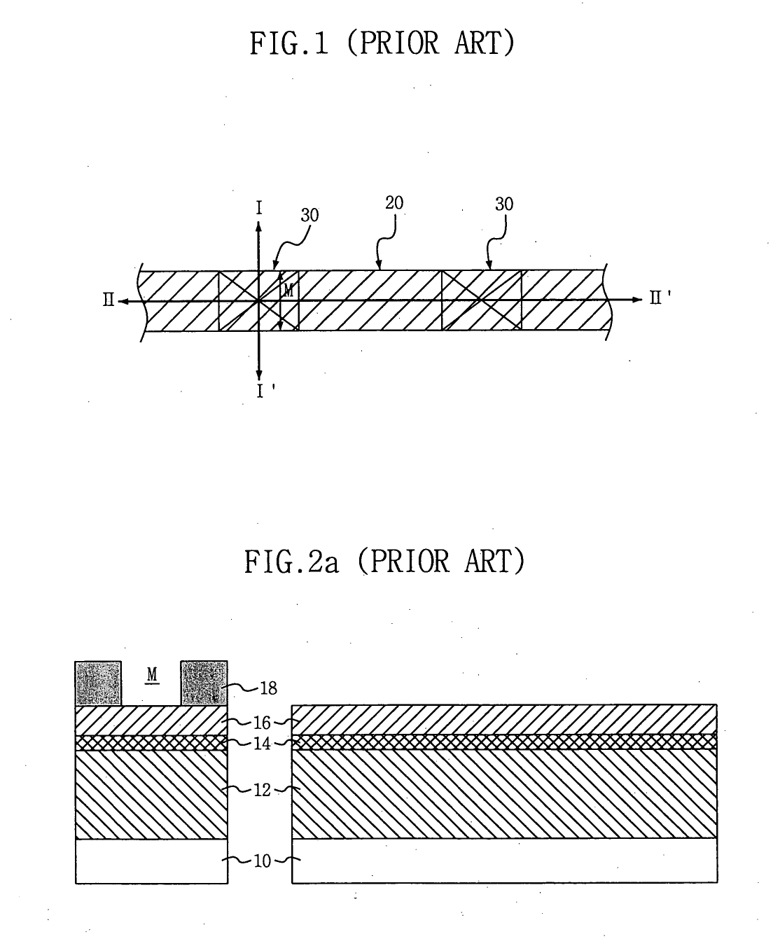

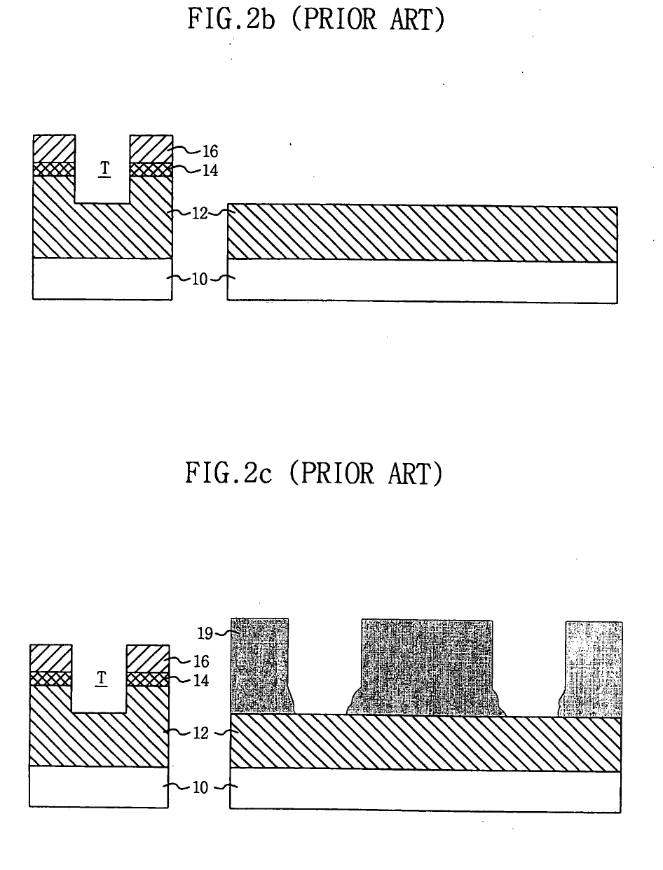

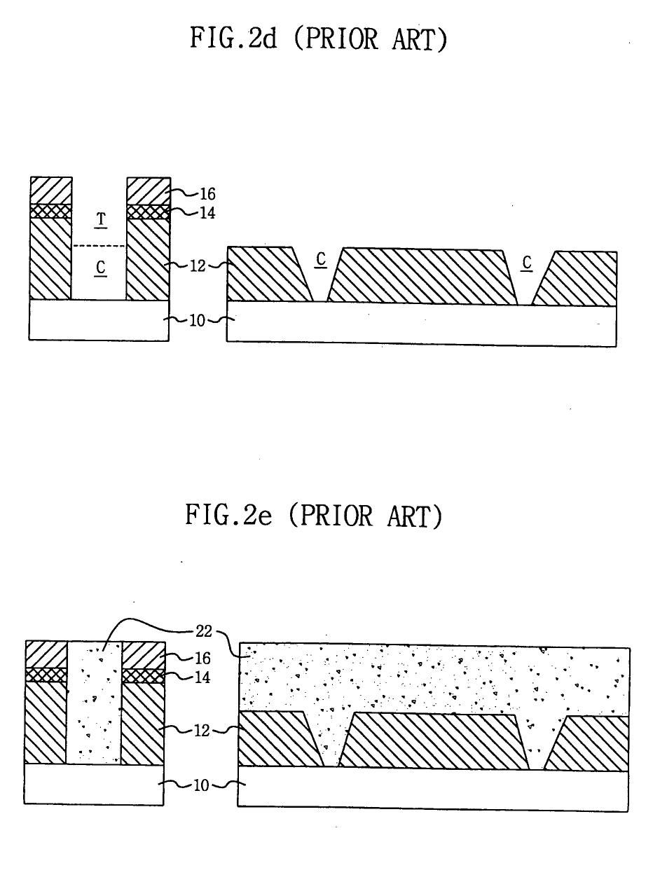

### DETAILED DESCRIPTION OF THE INVENTION

The present invention will now be described more fully with reference to the accompanying drawings, in which several exemplary embodiments of the invention are shown. In the drawings, the thickness of layers is exaggerated for clarity. Additionally, a layer described as being ‘on’ another layer or substrate may either be formed directly on top of the other layer or substrate or there may be intervening layers between them.

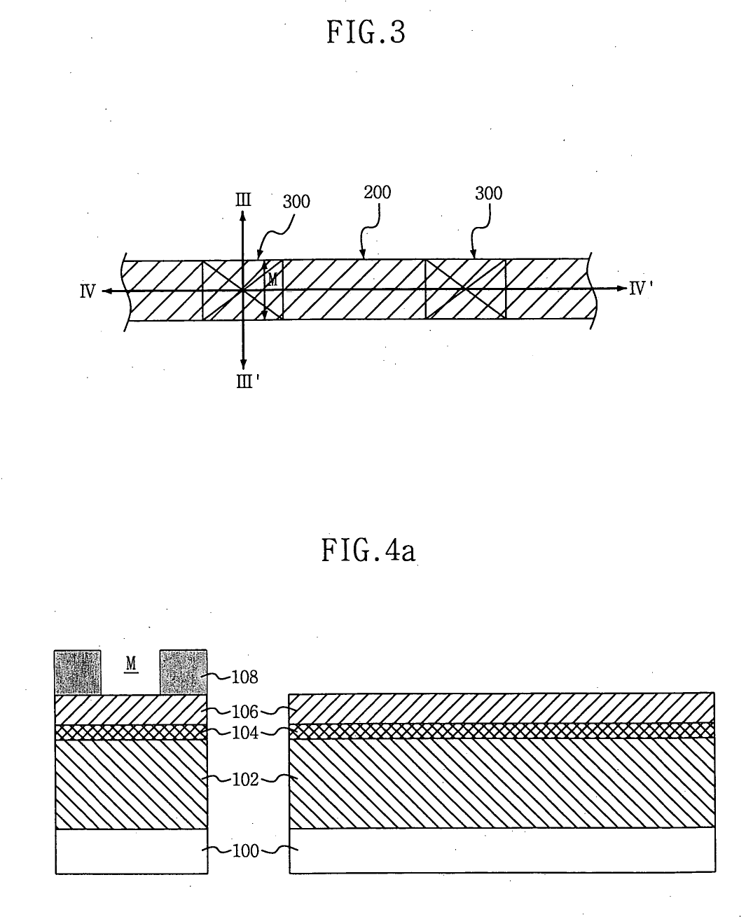

FIG. 3 is a planar view illustrating a layout of interconnection lines formed in a semiconductor device according to one embodiment the present invention.

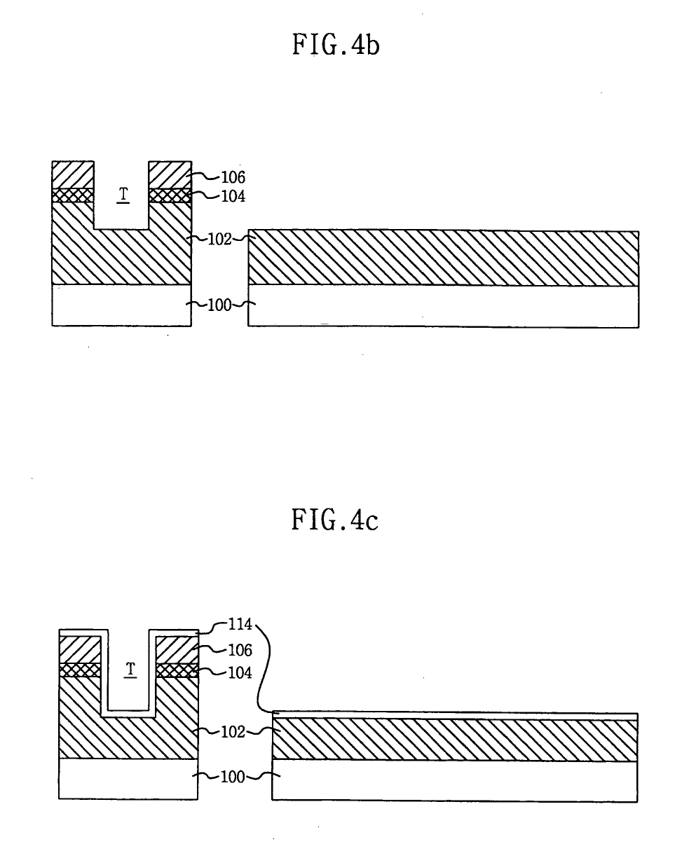

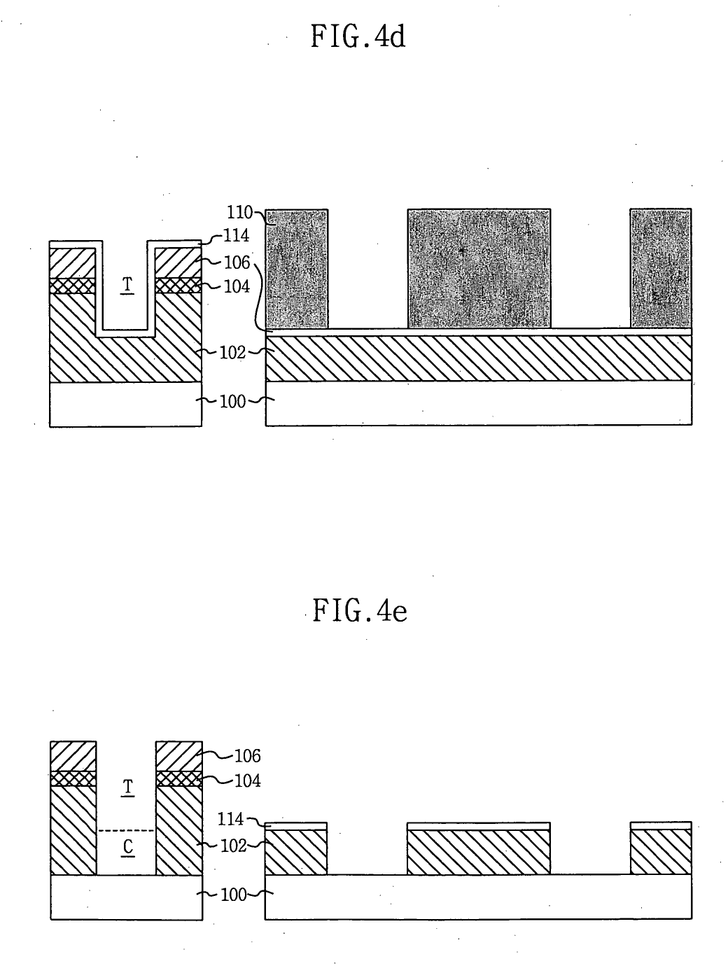

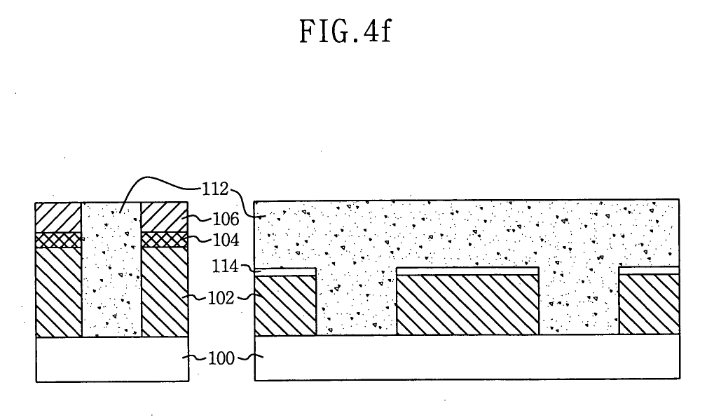

Referring to FIG. 3, a layout of interconnection lines formed in a semiconductor device comprises an interconnection line 200 formed on an insulating interlayer 102 (See, FIG. 4a), which acts to electrically insulate various elements in a semiconductor substrate 100 (See, FIG. 4a). The layout of interconnection lines further comprises a contact 300, which selectively connects various device elements formed under insulating interlayer 102 or semiconductor substrate 100 to interconnection line 200. Interconnection line 200 and contact 300 have a dual damascene structure.

FIGS. 4a through 4f are cross-sectional views illustrating a method of forming interconnection lines in a semiconductor device. Figures on the left side of FIGS. 4a through 4f, are cross-sectional views taken along a line between III and III′ in FIG. 3. Figures on the right side of FIGS. 4a through 4f, are cross-sectional views taken along a line between IV and IV′ in FIG. 3.

Referring to FIG. 4a, insulating interlayer 102 is formed on semiconductor substrate 100 by chemical vapor deposition (CVD). A hard mask layer 104 and a preventive reflection layer 106 are sequentially formed on insulating interlayer 102. Photoresist is further deposited on preventive reflection layer 106, and a first photoresist pattern 108 in the shape of interconnection line 200 is formed using a photolithography process. A plurality of conductive structures are typically further formed between insulating interlayer 102 and semiconductor substrate 100, wherein various electrodes such as a transistor gate electrode or connection lines are electrically insulated. Insulating interlayer 102 is typically formed using a silicon oxide layer having a thickness of about 4500 to 5000 Å and hard mask layer 104 is typically formed using a silicon nitride layer having a thickness of about 300 to 700 Å. Preventive reflection layer 106 is formed using a silicon oxy-nitride layer having a thickness of about 500 to 1000 Å. Insulating interlayer 102, hard mask layer 104, and preventive reflection layer 106 are typically formed in-situ using a single chamber during the CVD. Alternatively, different chambers may be used to form each layer during additional processes after insulating interlayer 102 is formed. Following the formation of preventive reflection layer 106, the photoresist is selectively exposed to a KrF or ArF light source using a reticle or photomask in a photolithography process. First photoresist pattern 108 has an opening of width M which defines interconnection line 200, which is formed later.

Referring to FIG. 4b, using first photoresist pattern 108 (See, FIG. 4a) as an etch mask, preventive reflection layer 106, hard mask layer 104, and insulating interlayer 102 are partially removed using a dry etching process, thereby forming a trench T or a groove. Once trench T is formed, first photoresist pattern 108 is removed. The dry etching process is performed by supplying reactant gases sequentially to one chamber. Each of the reactant gases has its own etch selectivity relative to preventive reflection layer 106, hard mask layer 104, and insulating interlayer 102, respectively. Furthermore, the dry etching process performs a timed etching process to etch insulating interlayer 102. In other words, the silicon oxide layer is set for a predetermined time depending on the etch rate of the silicon oxide layer, since an etch stop point cannot be used while etching of insulating interlayer 102.

The width of trench T typically ranges from about 850 to 2000 Å, and is preferably 1400 Å. The depth of the trench T below insulating interlayer 102 typically ranges from about 2000 to 3000 Å, and is preferably, 2500 Å. The critical dimension of trench T is typically about 1400 Å.

Referring to FIG. 4c, a scattered reflection layer 114 having a predetermined thickness is formed on semiconductor substrate 100. Scattered reflection layer 114 typically comprises a silicon oxide layer formed using a thermal treatment oxidation process. The silicon oxide layer is formed on preventive reflection layer 106 and on inner surfaces of trench T. The silicon oxide layer is typically formed with a substantially uniform thickness ranging from about 50 to 300 Å.

Referring to FIG. 4d, photoresist is deposited on semiconductor substrate 100 after reflection layer 114 is formed thereon. Using the photolithography process, a second photoresist pattern 110 intersecting trench T in the shape of at least two bars or dots is formed. Second photoresist pattern 110 is formed to have an opening greater than or equal to the width of trench T. Photoresist used during the formation of second photoresist pattern 110 is exposed to a KrF or ArF light source. Second photoresist pattern 110 cannot be formed to have an opening smaller than the wavelength of the KrF or ArF light source.

Where the photoresist is deposited on semiconductor substrate 100 using spin, the photoresist is formed on the flat surface of semiconductor substrate 100. Where the photoresist is deposited using a dual damascene process, the photoresist formed inside trench T is typically formed relatively thicker than the photoresist formed on the flat surface of semiconductor substrate 100. Therefore, it is important to supply sufficient exposure energy to the bottom of trench T during the exposure process.

Where sufficient exposure energy is supplied to the bottom of trench T during the exposure process, the photoresist on the bottom of trench T is readily removed when the photoresist is developed, thereby preventing the generation of photoresist scum. For example, consider the case where insulating interlayer 102 is formed using a silicon oxide layer having a transparent original color, hard mask layer 104 is formed of a silicon nitride layer having a translucent gray original color, and the preventive reflection layer 106 is formed using a silicon oxy-nitride layer having an opaque black original color. Since scattered reflection layer 114 is formed using a silicon oxide layer to increase the reflection rate of preventive reflection layer 106, sufficient exposure energy is supplied deep down in trench T, even to the photoresist formed on the bottom of trench T, thereby completely removing the photoresist formed on the bottom of trench T during the process of developing the exposed photoresist.

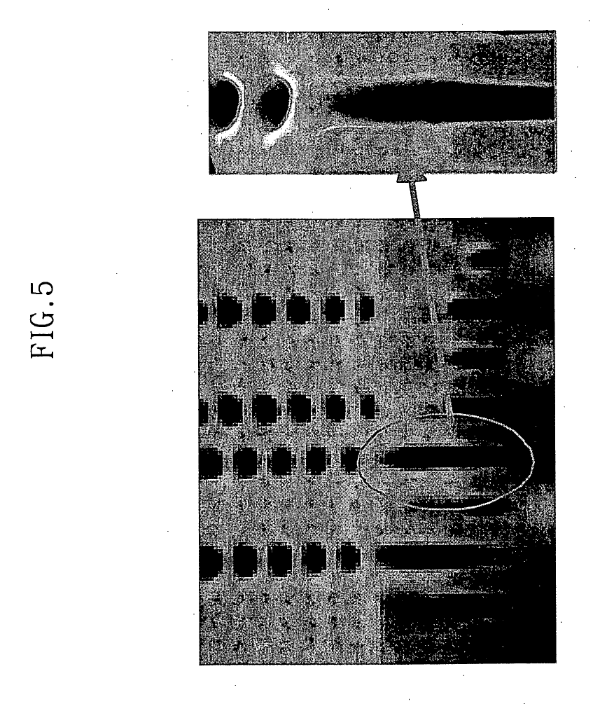

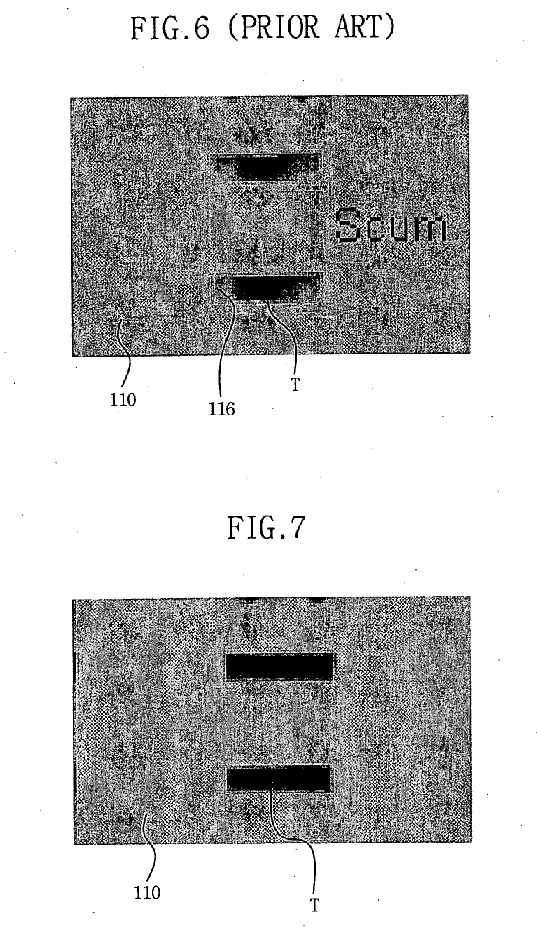

Meanwhile, in the case of forming a contact hole C (See, FIG. 4e) in trench T using a single silicon oxide layer, even where the photoresist is formed as thick as the depth of trench T, an open defect as shown in FIG. 5 does not occur due to photoresist scum 116 (See, FIG. 6). This is because the optical energy reflection rate of the light source is increased by scattered reflection on the sidewalls of trench T due to the silicon oxide layer. The increased optical energy reflection rate causes photoresist to be sufficiently exposed to remove it completely. As a result, photoresist scum 116 is completely eliminated.

Where an opening having bar or dot shaped patterns different from a typical dual damascene structure is formed in trench T, i.e., where trench T is formed from a plurality of different layers, photoresist scum 116 is often generated. An open defect is generated during a subsequent etching process, since photoresist filling trench T is not exposed to the light source, and the photoresist inside trench T is not removed during the development process. More specifically, photoresist scum 116 is generated on the bottom of trench T adjacent to the second photoresist pattern as in the conventional case, because the photoresist on the bottom of trench T is not exposed for lack of sufficient exposure energy. In other words, where trench T is formed from a plurality of different insulating layers including the silicon oxide layer and preventive reflection layer 106, preventive reflection layer 106 absorbs exposure energy, and thus, the inside of trench T lacks the exposure energy necessary to expose photoresist on the bottom of trench T, thereby leaving photoresist scum 116 after the photoresist is developed.

Therefore, in the method of forming interconnection lines in a semiconductor device according to the present invention, photoresist formed on the bottom of trench T is sufficiently exposed, thereby preventing photoresist scum 116 from being generated inside trench T after the photoresist is developed, as shown in FIG. 7. The photoresist is sufficiently exposed because scattered reflection layer 114, which is formed to a predetermined thickness on the overall surface of semiconductor substrate 100 before photoresist is deposited in trench T, causes light irradiated on the photoresist inside trench T to be scattered, thereby increasing its reflection rate.

In other words, in the method of forming interconnection lines in a semiconductor device according to the present invention, scattered reflection layer 114 is formed with a predetermined thickness on the overall surface of semiconductor substrate 100 having trench T formed thereon. Sufficient exposure energy is supplied from the light source to photoresist on the bottom of trench T during the photolithography process used to form second photoresist pattern 110 intersecting trench T. Photoresist scum 116 is thereby prevented from being generated in the portion where a contact hole C (See, FIG. 4e) is formed, thereby improving the reliability of the interconnection lines.

Referring to FIG. 4e, scattered reflection layer 114 and a portion of insulating interlayer 102 formed inside trench T are removed by a dry etching process, using second photoresist pattern 110 as an etch mask, thereby forming contact hole C exposing a portion of semiconductor substrate 100. Second photoresist pattern 110 is then removed. Scattered reflection layer 114 formed inside trench T is removed by the reactant gas used in the dry etching process used to form the contact hole. Since the dry etching process selectively etches the silicon oxide layer, and the reactant gas provides the high vertical etching characteristics, insulating interlayer 102 is removed from the bottom of trench T, thereby forming contact hole C without significantly changing the width of trench T.

Referring to FIG. 4f, a metal layer 112 is formed on the overall surface of semiconductor substrate 100 including contact hole C. Metal layer 112 comprises copper having a predetermined thickness. Metal layer 112 is chemically and mechanically polished, or etch-backed, thereby planarizing semiconductor substrate 100 to expose preventive reflection layer 106 and thus, complete the formation of the interconnection lines in a semiconductor device.

In summary, the method of forming interconnection lines in a semiconductor device according to the present invention increases the reliability of interconnection lines by forming scattered reflection layer 114 to a predetermined thickness on the overall surface of semiconductor substrate 100 having trench T formed therein. This allows sufficient energy from the light source used in the photolithography process used to form second photoresist pattern 110 to expose photoresist deep inside trench T, thereby preventing the generation of photoresist scum 116 in the portion where contact hole C is formed.

As described above, in the method of forming interconnection lines in a semiconductor device according to the present invention, a silicon oxide layer having a predetermined thickness is formed on the overall surface of semiconductor substrate 110 having trench T formed thereon, and photoresist inside trench T is supplied with sufficient exposure energy from a light source during used in a photolithography process used to form second photoresist pattern 110 across trench T, to prevent photoresist scum 116 from being generated at the portion where contact hole C is formed, thereby improving the reliability of the interconnection lines.

The preferred embodiments disclosed in the drawings and the corresponding written description are teaching examples. Those of ordinary skill in the art will understand that various changes in form and details may be made to the exemplary embodiments without departing from the scope of the present invention which is defined by the following claims.

1. A method of forming interconnection lines in a semiconductor device, comprising:
forming an insulating interlayer on a semiconductor substrate;
forming a preventive reflection layer on the insulating interlayer;
forming a first photoresist pattern on the preventive reflection layer;
removing the preventive reflection layer and a portion of the insulating interlayer to a predetermined depth, thereby forming a trench;
removing the first photoresist pattern;
forming a scattered reflection layer on the semiconductor substrate having the trench formed thereon;
forming a second photoresist pattern intersecting the trench;
forming a contact hole inside the trench using the second photoresist pattern as an etch mask, thereby exposing the semiconductor substrate;
forming a metal layer on the semiconductor substrate including the contact hole; and,
planarizing the semiconductor substrate to expose the preventive reflection layer or the insulating interlayer.

2. The method of claim 1, wherein the insulating interlayer comprises a silicon oxide layer.

3. The method of claim 1, wherein the insulating interlayer is formed with a thickness of about 4500 to 5000 Å.

4. The method of claim 1, further comprising forming a hard mask layer on the insulating interlayer.

5. The method of claim 4, wherein the hard mask layer comprises a silicon nitride layer.

6. The method of claim 1, wherein the hard mask layer is formed with a thickness of about 500 Å.

7. The method of claim 1, wherein the preventive reflection layer comprises a silicon oxy-nitride layer.

8. The method of claim 1, wherein the preventive reflection layer is formed with a thickness of about 800 Å.

9. The method of claim 1, wherein the first photoresist pattern or the second photoresist pattern is formed using a KrF or ArF light source.

10. The method of claim 1, wherein the trench is formed with a critical dimension of about 1400 Å.

11. The method of claim 1, wherein the trench is formed to have a depth of about 2500 Å below the surface of the insulating interlayer by performing a timed etching process.

12. The method of claim 1, wherein the scattered reflection layer comprises a silicon oxide layer.

13. The method of claim 12, wherein the silicon oxide layer is formed using a thermal treatment oxidation process.

14. The method of claim 1, wherein the scattered reflection layer is formed with a substantially uniform thickness.

15. The method of claim 1, wherein the scattered reflection layer is formed with a thickness of about 100 Å.

16. The method of claim 1, wherein the second photoresist pattern has the shape of at least two bars or dots.

17. The method of claim 1, wherein planarizing the semiconductor substrate comprises:
chemically and mechanically polishing the metal layer.

18. A method of forming interconnection lines in a semiconductor device, comprising:
forming an insulating interlayer on a semiconductor substrate;
forming a hard mask layer on the insulating interlayer;
forming a preventive reflection layer on the insulating interlayer;
forming a first photoresist pattern on the preventive reflection layer;
removing the preventive reflection layer and a portion of the insulating interlayer to a predetermined depth, thereby forming a trench;
removing the first photoresist pattern;
forming a scattered reflection layer on the semiconductor substrate having the trench formed thereon;
forming a second photoresist pattern intersecting the trench;
forming a contact hole inside the trench using the second photoresist pattern as an etch mask, thereby exposing the semiconductor substrate;
forming a metal layer on the semiconductor substrate including the contact hole; and,
planarizing the semiconductor substrate to expose the preventive reflection layer or the insulating interlayer.

19. The method of claim 18, wherein the first photoresist pattern or the second photoresist pattern is formed using a KrF or ArF light source.

20. The method of claim 18, wherein the scattered reflection layer comprises a silicon oxide layer.
